(19) United States
(12) Patent Application Publication
(10) Pub. No.: US 2026/0160829 A1
(43) Pub. Date: Jun. 11, 2026

(54) SHORT-CIRCUIT DETERMINATION CIRCUIT

(71) Applicant: YAZAKI CORPORATION, Tokyo (JP)

(72) Inventor: Hiromichi Hanaoka, Makinohara-shi (JP)

(21) Appl. No.: 19/181,349

(22) Filed: Apr. 17, 2025

Related U.S. Application Data
(63) Continuation of application No. PCT/JP2024/001793, filed on Jan. 23, 2024.

(30) Foreign Application Priority Data
Feb. 27, 2023 (JP) 2023-027920

(51) Int. Cl. G01R 31/52; G01R 31/40; H02H 7/18

(52) U.S. Cl. CPC G01R 31/52; G01R 31/40; H02H 7/18

(57) ABSTRACT

A short-circuit determination circuit includes a current detection unit, a voltage detection unit, a current abnormality determination unit, a voltage abnormality determination unit, and a short-circuit determination unit. The current detection unit detects current flowing to a power circuit. The voltage detection unit detects voltage applied to the power circuit. The current abnormality determination unit determines current abnormality based on a current value of the current detected by the current detection unit and a previously determined current threshold. The voltage abnormality determination unit determines voltage abnormality based on a voltage value of the voltage detected by the voltage detection unit and a previously determined voltage threshold. The short-circuit determination unit determines an electric connection abnormality, for example, a short circuit, based on a determination result from the determination by the current abnormality determination unit and a determination result from the determination by the voltage abnormality determination unit.

### CROSS-REFERENCE TO RELATED APPLICATION(S)

This application is a continuation application of International Application No. PCT/JP2024/001793 filed on Jan. 23, 2024 which claims the benefit of priority from Japanese Patent Application No. 2023-027920 filed on Feb. 27, 2023 and designating the U.S., the entire contents of which are incorporated herein by reference.

### BACKGROUND OF THE INVENTION

### 1. Field of the Invention

The present invention relates to a short-circuit determination circuit.

### 2. Description of the Related Art

Conventionally, for example, JP 2017-028 971 A describes a power device capable of interrupting respective currents that flow in both directions at a high response rate. The power device includes a power converter that converts the power of a power source to output the converted power to a load, a switch connected between the power source and the power converter, a first rectifier circuit and a second rectifier circuit that are connected to a path for current from the power source to the power converter through the switch, and a switching circuit connected in parallel to at least either the first rectifier circuit or the second rectifier circuit, in which the first rectifier circuit and the second rectifier circuit each allow current to pass only in its forward direction and are connected in series to the path for current such that their forward directions are counter to each other.

The power device described in Patent Literature 1 described above turns off the switching circuit in an emergency to cause the first rectifier circuit and the second rectifier circuit to interrupt the currents in the both directions at a high response rate. As such an emergency, for example, a short circuit is conceivable. Then, the power device is desired to determine such a short circuit promptly and accurately.

### SUMMARY OF THE INVENTION

Thus, the present invention has been made in consideration of the above and an object of the present invention is to provide a short-circuit determination circuit capable of determining a short circuit properly.

In order to achieve the above mentioned object, a short-circuit determination circuit according to one aspect of the present invention includes a current detection unit that detects current flowing to a power circuit; a voltage detection unit that detects voltage applied to the power circuit; a current abnormality determination unit that determines current abnormality based on a current value of the current detected by the current detection unit and a previously determined current threshold; a voltage abnormality determination unit that determines voltage abnormality based on a voltage value of the voltage detected by the voltage detection unit and a previously determined voltage threshold; and a short-circuit determination unit that determines a short circuit in the power circuit based on a determination result from the determination by the current abnormality determination unit and a determination result from the determination by the voltage abnormality determination unit, wherein the power circuit is provided ranging between a first electrical device and a second electrical device, the first electrical device is a main battery capable of supplying power, the second electrical device is a sub-battery that is connected to the main battery through an interrupting circuit and is capable of supplying power, the current detection unit detects current flowing between the main battery and the sub-battery, the voltage detection unit detects voltage applied between the main battery and the sub-battery, and in a case where the current abnormality is determined by the current abnormality determination unit and the voltage abnormality is determined by the voltage abnormality determination unit, the short-circuit determination unit determines the short circuit and disconnects the interrupting circuit, and at power on, the interrupting circuit is placed in the disconnected state, and the interrupting circuit is energized when a short circuit abnormality is not detected in the disconnected state and a wake up condition is fulfilled.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a circuit diagram illustrating an exemplary configuration of a power device according to an embodiment;

FIG. 2 illustrates transitions in the state of an interrupting circuit according to the embodiment;

FIG. 3 illustrates an exemplary operation of a short-circuit determination circuit according to the embodiment;

FIG. 4 illustrates exemplary determination of the short-circuit determination circuit according to the embodiment; and

FIG. 5 is a flowchart illustrating an exemplary operation of the short-circuit determination circuit according to the embodiment.

### DETAILED DESCRIPTION OF THE PREFERRED EMBODIMENTS

Modes (embodiments) for carrying out the present invention will be described in detail with reference to the drawings. The present invention is not limited to the contents described in the following embodiments. In addition, the following constituent elements include constituent elements conceivable easily by those skilled in the art and substantially the same constituent elements. Furthermore, the following configurations can be combined as appropriate. In addition, various omissions, replacements, or alterations can be made in terms of configuration without departing from the gist of the present invention.

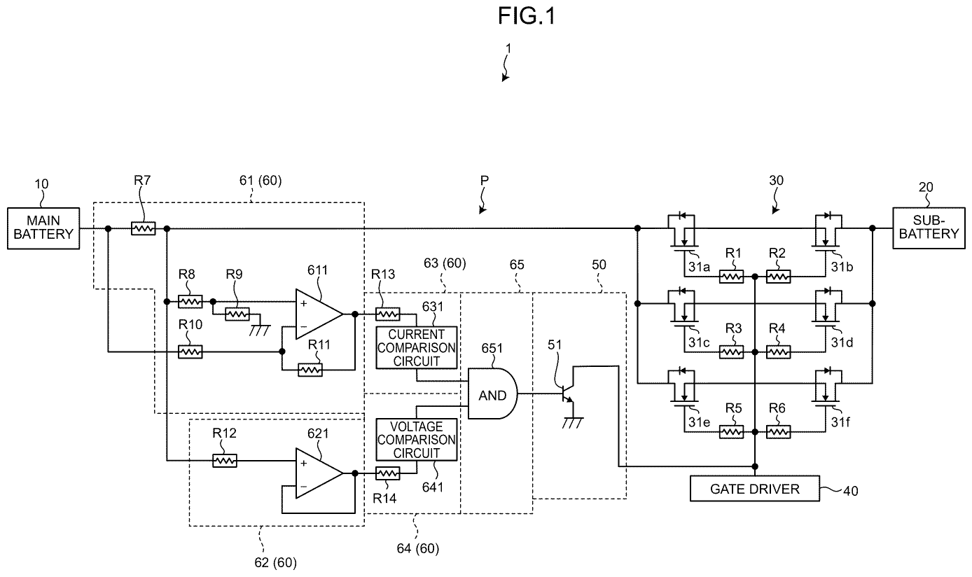

A power device 1 according to an embodiment will be described with reference to the drawings. The power device 1 is mounted on a vehicle and supplies power to a load unit in the vehicle. For example, the power device 1 determines an electric connection abnormality, such as a short circuit or a ground fault (leak), in a power circuit P and disconnects a power supply route. As illustrated in FIG. 1, the power device 1 includes the power circuit P, a main battery 10 as a first electrical device, a sub-battery 20 as a second electrical device, an interrupting circuit 30, a gate driver 40, a gate driver control unit 50, and a short-circuit determination circuit 60. The power circuit P is provided ranging between the main battery 10 and the sub-battery 20.

The main battery 10 serves as a power-rechargeable storage battery capable of supplying power and is, for example, a lead-acid battery or a lithium-ion battery. The main battery 10 supplies power to a load unit mounted on the vehicle. The main battery 10 is connected to the sub-battery 20 through the interrupting circuit 30 and charges the sub-battery 20.

The sub-battery 20 serves as a power-rechargeable storage battery capable of supplying power and is, for example, a lead-acid battery or a lithium-ion battery. The sub-battery 20 supplies power to a load unit mounted on the vehicle. The sub-battery 20 is connected to the main battery 10 through the interrupting circuit 30 and stores the power supplied from the main battery 10.

The interrupting circuit 30 interrupts current and is, for example, a back-to-back circuit. The interrupting circuit 30 includes a pair of FETs 31a and 31b, a pair of FETs 31c and 31d, a pair of FETs 31e and 31f, and resistors R1 to R6. The FETs 31a to 31f are each, for example, an N-channel MOSFET. The three pairs of FETs are mutually connected in parallel.

Specifically, the pair of FETs 31a and 31b have respective source terminals connected to each other. The FET 31a has a drain terminal connected to the main battery 10 and a gate terminal connected to the gate driver 40 through the resistor R1. The FET 31b has a drain terminal connected to the sub-battery 20 and a gate terminal connected to the gate driver 40 through the resistor R2. The pair of FETs 31a and 31b turn on in response to application of voltage to their gate terminals to establish a connection between the main battery 10 and the sub-battery 20 for bidirectional energization. The pair of FETs 31a and 31b are off in a case where no voltage is applied to their gate terminals such that bidirectional energization is disabled by a disconnection between the main battery 10 and the sub-battery 20.

The pair of FETs 31c and 31d have respective source terminals connected to each other. The FET 31c has a drain terminal connected to the main battery 10 and a gate terminal connected to the gate driver 40 through the resistor R3. The FET 31d has a drain terminal connected to the sub-battery 20 and a gate terminal connected to the gate driver 40 through the resistor R4. The pair of FETs 31c and 31d turn on in response to application of voltage to their gate terminals to establish a connection between the main battery 10 and the sub-battery 20 for bidirectional energization. The pair of FETs 31c and 31d are off in a case where no voltage is applied to their gate terminals such that bidirectional energization is disabled by a disconnection between the main battery 10 and the sub-battery 20.

The pair of FETs 31e and 31f have respective source terminals connected to each other. The FET 31e has a drain terminal connected to the main battery 10 and a gate terminal connected to the gate driver 40 through the resistor R5. The FET 31f has a drain terminal connected to the sub-battery 20 and a gate terminal connected to the gate driver 40 through the resistor R6. The pair of FETs 31e and 31f turn on in response to application of voltage to their gate terminals to establish a connection between the main battery 10 and the sub-battery 20 for bidirectional energization. The pair of FETs 31e and 31f are off in a case where no voltage is applied to their gate terminals such that bidirectional energization is disabled by a disconnection between the main battery 10 and the sub-battery 20.

The gate driver 40 controls the interrupting circuit 30. The gate driver 40 is connected to the respective gate terminals of the FETs 31a to 31f in the interrupting circuit 30. The gate driver 40 applies voltage to the gate terminals to turn on the FETs 31a to 31f and stops the application of voltage to the gate terminals to turn off the FETs 31a to 31f.

The gate driver control unit 50 controls the gate driver 40 based on a command from the short-circuit determination circuit 60. The gate driver control unit 50 includes a transistor 51. The transistor 51 is, for example, an npn-type bipolar transistor and has a collector terminal connected between the gate driver 40 and the respective gate terminals of the FETs 31a to 31f, an emitter terminal connected to the ground, and a base terminal connected to the short-circuit determination circuit 60. In a case where the transistor 51 turns on in response to application of voltage by the short-circuit determination circuit 60, a collector current (current output from the gate driver 40) flows from the collector terminal to the emitter terminal, so that the application of voltage to each gate terminal by the gate driver 40 is stopped. Therefore, the transistor 51 can turn off the FETs 31a to 31f. On the other hand, in a case where the transistor 51 is off due to no application of voltage by the short-circuit determination circuit 60, no collector current flows from the collector terminal to the emitter terminal and thus the application of voltage to each gate terminal by the gate driver 40 continues. Therefore, the transistor 51 can keep the FETs 31a to 31f on.

The short-circuit determination circuit 60 determines an electric connection abnormality, such as a short circuit or a ground fault. For example, in a case where the short-circuit determination circuit 60 determines that the main battery 10 has a ground fault, the short-circuit determination circuit 60 disconnects the interrupting circuit 30. The short-circuit determination circuit 60 includes a current detection unit 61, a voltage detection unit 62, a current abnormality determination unit 63, a voltage abnormality determination unit 64, and a short-circuit determination unit 65.

The current detection unit 61 detects current. In this example, the current detection unit 61 detects the current flowing between the main battery 10 and the sub-battery 20. The current detection unit 61 includes a shunt resistor R7, a current amplifier circuit 611, and resistors R8 to R11.

The shunt resistor R7 is provided between the main battery 10 and the sub-battery 20 and has one end connected to the main battery 10 and the other end connected to the sub-battery 20.

The current amplifier circuit 611 amplifies current. The current amplifier circuit 611 has a non-inverting input terminal (+), an inverting input terminal (−), and an output terminal. The non-inverting input terminal (+) is connected between the sub-battery 20 and the shunt resistor R7 through the resistor R8. The inverting input terminal (−) is connected between the shunt resistor R7 and the main battery 10 through the resistor R10 and is connected to the output terminal through the resistor R11. The output terminal is connected to the current abnormality determination unit 63. The resistor R9 has one end connected between the resistor R8 and the non-inverting input terminal (+) and the other end connected to the ground. The resistor R9 divides the voltage applied to the shunt resistor R7. The gain of the current amplifier circuit 611 is determined based on the ratio in resistance between the resistor R10 and the resistor R11. The current amplifier circuit 611 outputs, to the current abnormality determination unit 63, an amplified voltage (current value) resulting from amplification of the voltage applied to the shunt resistor R7.

The voltage detection unit 62 detects voltage. In this example, the voltage detection unit 62 detects the voltage applied between the main battery 10 and the sub-battery 20. The voltage detection unit 62 includes a voltage amplifier circuit 621 and a resistor R12.

The voltage amplifier circuit 621 amplifies voltage. The voltage amplifier circuit 621 has a non-inverting input terminal (+), an inverting input terminal (−), and an output terminal. The non-inverting input terminal (+) is connected between the main battery 10 and the sub-battery 20 through the resistor R12. The non-inverting input terminal (+) is connected, for example, between the shunt resistor R7 and the sub-battery 20. The inverting input terminal (−) is connected to the output terminal. The output terminal is connected to the voltage abnormality determination unit 64. The voltage amplifier circuit 621 serves as a voltage follower and has a gain of 1. The voltage amplifier circuit 621 outputs, to the voltage abnormality determination unit 64, an amplified voltage (voltage value) resulting from amplification of the voltage applied between the main battery 10 and the sub-battery 20. Note that the voltage follower may be omitted depending on the configuration of a voltage comparison circuit 641 subsequent thereto.

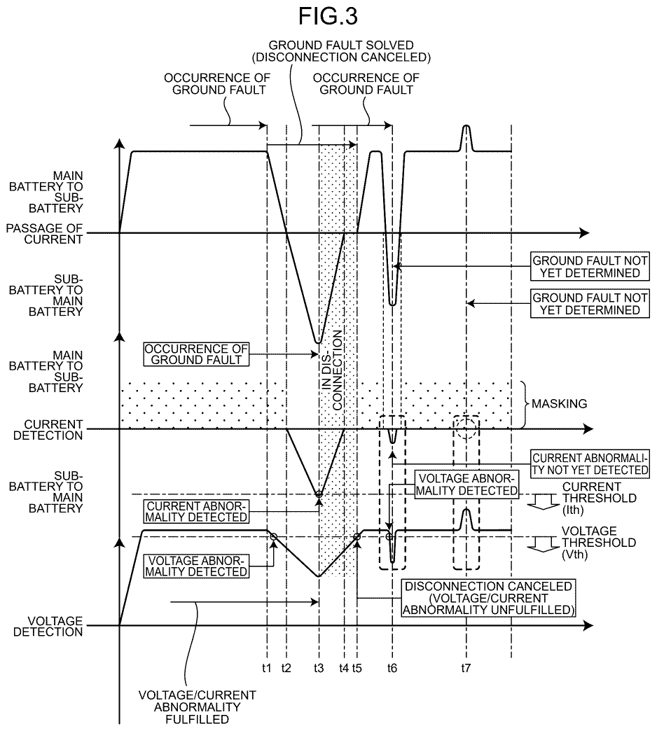

The current abnormality determination unit 63 determines an abnormality in current. For example, based on the current value of the current detected by the current detection unit 61 and a previously determined current threshold Ith (refer to FIG. 3), the current abnormality determination unit 63 determines current abnormality. The current abnormality determination unit 63 includes a current comparison circuit 631 and a resistor R13.

The current comparison circuit 631 serves as a comparison circuit for comparison between current values. The current comparison circuit 631 is connected to the current amplifier circuit 611 through the resistor R13 and compares the current value (amplified voltage) output from the current amplifier circuit 611 and the current threshold Ith. In a case where the current value is greater than or equal to the current threshold Ith, the current comparison circuit 631 outputs, to the short-circuit determination unit 65, a current abnormality signal (High level signal) indicating current abnormality. On the other hand, in a case where the current value output from the current amplifier circuit 611 is less than the current threshold Ith, the current comparison circuit 631 outputs, to the short-circuit determination unit 65, a current normality signal (Low level signal) indicating current normality.

The voltage abnormality determination unit 64 determines an abnormality in voltage. For example, based on the voltage value of the voltage detected by the voltage detection unit 62 and a previously determined voltage threshold Vth (refer to FIG. 3), the voltage abnormality determination unit 64 determines voltage abnormality. The voltage abnormality determination unit 64 includes the voltage comparison circuit 641 and a resistor R14.

The voltage comparison circuit 641 serves as a comparison circuit for comparison between voltage values. The voltage comparison circuit 641 is connected to the voltage amplifier circuit 621 through the resistor R14 and compares the voltage value (amplified voltage) output from the voltage amplifier circuit 621 and the voltage threshold Vth. In a case where the voltage value is less than the voltage threshold Vth, the voltage comparison circuit 641 outputs, to the short-circuit determination unit 65, a voltage abnormality signal (High level signal) indicating voltage abnormality. On the other hand, in a case where the voltage value output from the voltage amplifier circuit 621 is greater than or equal to the voltage threshold Vth, the voltage comparison circuit 641 outputs, to the short-circuit determination unit 65, a voltage normality signal (Low level signal) indicating voltage normality.

The short-circuit determination unit 65 determines an electric connection abnormality, such as a short circuit or a ground fault. For example, based on a determination result from determination by the current abnormality determination unit 63 and a determination result from determination by the voltage abnormality determination unit 64, the short-circuit determination unit 65 determines a short circuit. For example, in a case where the current abnormality determination unit 63 determines current abnormality and the voltage abnormality determination unit 64 determines voltage abnormality, the short-circuit determination unit 65 determines a short circuit and disconnects the interrupting circuit 30. The short-circuit determination unit 65 includes an AND circuit 651.

The AND circuit 651 includes a first input terminal, a second input terminal, and an output terminal. The first input terminal is connected to the current comparison circuit 631. The second input terminal is connected to the voltage comparison circuit 641. The output terminal is connected to the transistor 51 of the gate driver control unit 50. The AND circuit 651 is a logical conjunction circuit that performs logical conjunction. In a case where the first input terminal and the second input terminal receive respective High level signals, the AND circuit 651 outputs a disconnection signal to the transistor 51. For example, as the disconnection signal, the AND circuit 651 applies voltage to the transistor 51 to turn on the transistor 51. On the other hand, in a case where at least either the first input terminal or the second input terminal receives a Low level signal, the AND circuit 651 does not output the disconnection signal to the transistor 51. For example, the AND circuit 651 applies no voltage to the transistor 51 to keep the transistor 51 off. In this example, in a case where the current comparison circuit 631 outputs a High level signal (current abnormality signal) and the voltage comparison circuit 641 outputs a High level signal (voltage abnormality signal), namely, in a case where, for example, a ground fault is detected, the AND circuit 651 turns on the transistor 51 to disconnect the interrupting circuit 30. On the other hand, in a case where at least either the current comparison circuit 631 or the voltage comparison circuit 641 outputs a Low level signal, namely, in a case where, for example, no ground fault is detected, the AND circuit 651 keeps the transistor 51 off such that the state of the interrupting circuit 30 remains in energization.

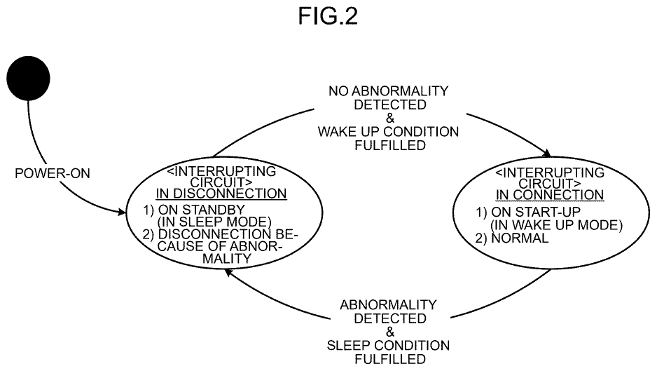

Next, transition in the state of the power device 1 having such a configuration as described above will be described. For example, as illustrated in FIG. 2, in response to power-on, the power device 1 causes the state of the interrupting circuit 30 to transition into disconnection. Then, in a case where the short-circuit determination circuit 60 detects no abnormality, such as a ground fault, and a wake up condition for starting up the power device 1 is fulfilled at power-on, the power device 1 causes the state of the interrupting circuit 30 to transition into energization. In a case where the short-circuit determination circuit 60 detects an abnormality, such as a ground fault, and a sleep condition for keeping the power device 1 on standby is fulfilled after the state of the interrupting circuit 30 transitions into energization, the power device 1 causes the state of the interrupting circuit 30 to transition into disconnection. In this manner, after power-on, the state of the power device 1 transitions.

Next, an exemplary operation of the power device 1 will be described. In this example, a case where current flows from the main battery 10 to the sub-battery 20 with the power device 1 normal is assumed. In the power device 1, for example, as illustrated in FIG. 3, in a case where a ground fault occurs in the main battery 10 (at time t1), current flows as backflow from the sub-battery 20 to the main battery 10 (at time t2). At this time, in a case where the voltage value output from the voltage amplifier circuit 621 is less than the voltage threshold Vth, the voltage comparison circuit 641 outputs, to the AND circuit 651, a voltage abnormality signal (High level signal) indicating voltage abnormality (between time t1 and time t2). In a case where the current value output from the current amplifier circuit 611 is greater than or equal to the current threshold Ith, the current comparison circuit 631 outputs, to the AND circuit 651, a current abnormality signal (High level signal) indicating current abnormality (at time t3).

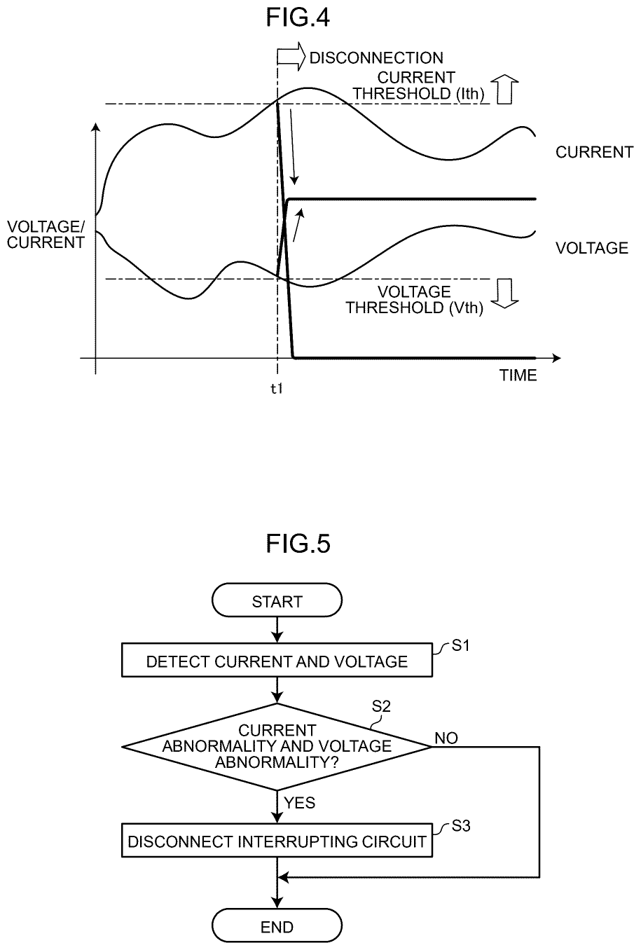

In a case where the current comparison circuit 631 outputs the current abnormality signal (High level signal) and the voltage comparison circuit 641 outputs the voltage abnormality signal (High level signal), the AND circuit 651 determines a short circuit (ground fault) and outputs a disconnection signal to turn on the transistor 51 of the gate driver control unit 50 for disconnection of the interrupting circuit 30 (at time t3 in FIG. 3, at time t1 in FIG. 4). The gate driver control unit 50 includes a latch circuit (not illustrated). In response to the disconnection signal output from the AND circuit 651, until the current comparison circuit 631 outputs a current normality signal (Low level signal) and the voltage comparison circuit 641 outputs a voltage normality signal (Low level signal), the latch circuit keeps the transistor 51 on such that the state of the interrupting circuit 30 remains in disconnection (time t3 to time t5). In a case where the current comparison circuit 631 outputs the current normality signal (Low level signal) and the voltage comparison circuit 641 outputs the voltage normality signal (Low level signal) after the interrupting circuit 30 is disconnected, the gate driver control unit 50 brings the state of the interrupting circuit 30 from the disconnection into energization (at time t5).

Note that, in a case where the current comparison circuit 631 outputs a current normality signal (Low level signal) when the voltage comparison circuit 641 outputs a voltage abnormality signal (High level signal), because the current value is normal even with the voltage value abnormal, the AND circuit 651 does not disconnect the interrupting circuit 30 (at time t6). In a case where an overcurrent flows from the main battery 10 to the sub-battery 20 when an overvoltage is applied between the main battery 10 and the sub-battery 20, due to masking by a mask circuit (not illustrated), the current detection unit 61 does not detect that the overcurrent flows (at time t7). Here, the mask circuit is a circuit that disables (masks), in a case where current flows from the main battery 10 to the sub-battery 20, the current to be detected by the current detection unit 61.

Next, an exemplary operation of the short-circuit determination circuit 60 will be described with reference to the flowchart. As illustrated in FIG. 5, in the short-circuit determination circuit 60, the current detection unit 61 detects the current flowing between the main battery 10 and the sub-battery 20, and the voltage detection unit 62 detects the voltage applied between the main battery 10 and the sub-battery 20 (Step S1). In a case where the short-circuit determination unit 65 determines, for example, a short circuit in a case where the current abnormality determination unit 63 determines current abnormality and the voltage abnormality determination unit 64 determines voltage abnormality (Step S2; Yes), the short-circuit determination unit 65 disconnects the interrupting circuit 30 (Step S3). In a case where the result based on the detections in Step S1 indicates at least either current normality or voltage normality (Step S2; No), the short-circuit determination unit 65 does not disconnect the interrupting circuit 30.

As above, the short-circuit determination circuit 60 according to the embodiment includes the current detection unit 61, the voltage detection unit 62, the current abnormality determination unit 63, the voltage abnormality determination unit 64, and the short-circuit determination unit 65. The current detection unit 61 detects the current flowing to the power circuit P. The voltage detection unit 62 detects the voltage applied to the power circuit P. Based on the current value of the current detected by the current detection unit 61 and the previously determined current threshold Ith, the current abnormality determination unit 63 determines current abnormality. Based on the voltage value of the voltage detected by the voltage detection unit 62 and the previously determined voltage threshold Vth, the voltage abnormality determination unit 64 determines voltage abnormality. Based on a determination result from the determination by the current abnormality determination unit 63 and a determination result from the determination by the voltage abnormality determination unit 64, the short-circuit determination unit 65 determines an electric connection abnormality, such as a short circuit or a ground fault (leak), in the power circuit P.

Due to this configuration, the short-circuit determination circuit 60 determines, for example, a short circuit based on both the current value and the voltage value. Thus, even without a filter circuit that removes noise, any malfunction due to micro noise can be inhibited, leading to accurate determination of a short circuit, for example. The short-circuit determination circuit 60 determines voltage abnormality based on the detected voltage value and the voltage threshold Vth, and thus a reduction can be made in the time from the time of occurrence of a short circuit to the time of determination of the short circuit, for example, in comparison to a case where voltage abnormality is determined based on the gradient of a change in voltage as a function of time. As a result, the short-circuit determination circuit 60 can determine, for example, a short circuit, properly.

In the short-circuit determination circuit 60, the power circuit P is provided ranging between the main battery 10 and the sub-battery 20. The sub-battery 20 is connected to the main battery 10 through the interrupting circuit 30. The current detection unit 61 detects the current flowing between the main battery 10 and the sub-battery 20. The voltage detection unit 62 detects the voltage applied between the main battery 10 and the sub-battery 20. In a case where the current abnormality determination unit 63 determines current abnormality and the voltage abnormality determination unit 64 determines voltage abnormality, the short-circuit determination unit 65 determines, for example, a short circuit and disconnects the interrupting circuit 30. Due to this configuration, the short-circuit determination circuit 60 can properly determine, for example, a short circuit between the main battery 10 and the sub-battery 20 to perform disconnection processing.

In the short-circuit determination circuit 60, the current detection unit 61 includes the current amplifier circuit 611, which amplifies current, and the shunt resistor R7. The voltage detection unit 62 includes the voltage amplifier circuit 621, which amplifies voltage. The current abnormality determination unit 63 includes the current comparison circuit 631, which compares currents. The voltage abnormality determination unit 64 includes the voltage comparison circuit 641, which compares voltages. The short-circuit determination unit 65 includes the AND circuit 651, which performs logical conjunction. The shunt resistor R7 is provided between the main battery 10 and the sub-battery 20. The current amplifier circuit 611 outputs, to the current comparison circuit 631, a current value resulting from amplification of the voltage applied to the shunt resistor R7. The voltage amplifier circuit 621 outputs, to the voltage comparison circuit 641, a voltage value resulting from amplification of the voltage applied between the main battery 10 and the sub-battery 20. In a case where the current value output from the current amplifier circuit 611 is greater than or equal to the current threshold Ith, the current comparison circuit 631 outputs, to the AND circuit 651, a current abnormality signal indicating current abnormality. In a case where the voltage value output from the voltage amplifier circuit 621 is less than the voltage threshold Vth, the voltage comparison circuit 641 outputs, to the AND circuit 651, a voltage abnormality signal indicating voltage abnormality. In a case where the current abnormality signal is output from the current comparison circuit 631 and the voltage abnormality signal is output from the voltage comparison circuit 641, the AND circuit 651 outputs a disconnection signal to the interrupting circuit 30 to disconnect the interrupting circuit 30. Due to this configuration, the short-circuit determination circuit 60 can properly determine, for example, a short circuit between the main battery 10 and the sub-battery 20 using analog circuits, such as the current amplifier circuit 611.

Note that an example in which the short-circuit determination circuit 60 includes analog circuits, such as the current amplifier circuit 611, has been given in the above description, but this is not limiting. Thus, for example, digital circuits may be provided.

An example in which the first electrical device is the main battery 10 and the second electrical device is the sub-battery 20 has been given above, but this is not limiting. Thus, the first electrical device and the second electrical device may be other electrical devices.

The power device 1 illustrated in FIG. 1 includes a circuit for detecting a ground fault that occurs on the side of the main battery 10 (passage of current: sub-battery to main battery in FIG. 3), but this is not limiting. For example, if the polarity of the current amplifier circuit (OP amplifier) 611 in the current detection unit 61 is inverted, the power device 1 can detect a ground fault on the side of the sub-battery 20. In this manner, the power device 1 does not limit the direction of detection of current. An example in which the power device 1 detects a ground fault on the side of the main battery 10 has been given, and thus current detection (passage of current: main battery to sub-battery) in FIG. 3 is not a target to be detected.

A short-circuit determination circuit according to the present embodiment can determine a short circuit based on both a current value and a voltage value, so that the short circuit can be determined accurately even without a filter circuit that removes noise. The short-circuit determination circuit determines voltage abnormality based on the detected voltage value and a voltage threshold and thus a reduction can be made in the time from the time of occurrence of the short circuit to the time of determination of the short circuit, for example, in comparison to a case where voltage abnormality is determined based on the gradient of a change in voltage as a function of time. As a result, the short-circuit determination circuit can determine the short circuit properly.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A short-circuit determination circuit comprising:
a current detection unit that detects current flowing to a power circuit;
a voltage detection unit that detects voltage applied to the power circuit;
a current abnormality determination unit that determines current abnormality based on a current value of the current detected by the current detection unit and a previously determined current threshold;
a voltage abnormality determination unit that determines voltage abnormality based on a voltage value of the voltage detected by the voltage detection unit and a previously determined voltage threshold; and
a short-circuit determination unit that determines a short circuit in the power circuit based on a determination result from the determination by the current abnormality determination unit and a determination result from the determination by the voltage abnormality determination unit, wherein
the power circuit is provided ranging between a first electrical device and a second electrical device,
the first electrical device is a main battery capable of supplying power,
the second electrical device is a sub-battery that is connected to the main battery through an interrupting circuit and is capable of supplying power,
the current detection unit detects current flowing between the main battery and the sub-battery,
the voltage detection unit detects voltage applied between the main battery and the sub-battery, and
in a case where the current abnormality is determined by the current abnormality determination unit and the voltage abnormality is determined by the voltage abnormality determination unit, the short-circuit determination unit determines the short circuit and disconnects the interrupting circuit, and
at power on, the interrupting circuit is placed in the disconnected state, and the interrupting circuit is energized when a short circuit abnormality is not detected in the disconnected state and a wake up condition is fulfilled.

2. The short-circuit determination circuit according to claim 1, wherein the current detection unit includes a current amplifier circuit that performs current amplification and a shunt resistor,
the voltage detection unit includes a voltage amplifier circuit that performs voltage amplification,
the current abnormality determination unit includes a current comparison circuit that performs current comparison,
the voltage abnormality determination unit includes a voltage comparison circuit that performs voltage comparison,
the short-circuit determination unit includes an AND circuit that performs logical conjunction,
the shunt resistor is provided between the main battery and the sub-battery,
the current amplifier circuit outputs, to the current comparison circuit, a current value resulting from amplification of voltage applied to the shunt resistor,
the voltage amplifier circuit outputs, to the voltage comparison circuit, a voltage value resulting from amplification of the voltage applied between the main battery and the sub-battery,
the current comparison circuit outputs, in a case where the current value output from the current amplifier circuit is greater than or equal to the current threshold, a current abnormality signal indicating the current abnormality to the AND circuit,
the voltage comparison circuit outputs, in a case where the voltage value output from the voltage amplifier circuit is less than the voltage threshold, a voltage abnormality signal indicating the voltage abnormality to the AND circuit, and
the AND circuit outputs, in a case where the current abnormality signal is output from the current comparison circuit and the voltage abnormality signal is output from the voltage comparison circuit, a disconnection signal to the interrupting circuit to disconnect the interrupting circuit.
